(19) United States
(12) Patent Application Publication
(10) Pub. No.: US 2026/0271678 A1
(43) Pub. Date: Sep. 10, 2026

(54) Methods for Reshaping Masking Layer Openings

(71) Applicant: Applied Materials, Inc., Santa Clara, CA (US)

(72) Inventors: Chen-Chih Hsu, Gloucester, MA (US); Yung-Chen Lin, Westwood, MA (US); Shurong Liang, Lynnfield, MA (US); Steven Sherman, Newton, MA (US)

(73) Assignee: Applied Materials, Inc., Santa Clara, CA (US)

(21) Appl. No.: 19/071,085

(22) Filed: Mar. 5, 2025

(51) Int. Cl. H01L 21/027; H01J 37/34

(52) U.S. Cl. CPC H10P 76/204; H01J 37/3464; H01J 2237/336

(57) ABSTRACT

A method of modifying an opening in a material layer provided on a substrate to achieve desired critical dimensions may include forming a plurality of openings in a material layer stack formed over a substrate, wherein each opening of the plurality of openings comprises a first side opposite a second side, a first end opposite a second end, and a set of connection areas between the first end and the first and second sides. The method may further include performing a first ion process on the material layer stack to modify one or more dimensions of the set of connection areas, wherein the first ion process comprises directing ions to the material layer stack at a first non-zero angle relative to a normal direction extending from a top surface of the material layer stack.

### FIELD OF THE DISCLOSURE

The present embodiments relate to semiconductor device patterning and, more particularly, to ion treatments to reshape openings in patterned masking layers.

### BACKGROUND OF THE DISCLOSURE

In the integrated circuit (IC) industry, functional density (i.e., the number of interconnected devices per wafer area) has generally increased while geometry size (i.e., the smallest component that can be created using a fabrication process) has decreased. This scaling down process generally provides benefits by increasing production efficiency and lowering associated costs. However, such scaling down introduces challenges in maintaining process variations at acceptable levels within a wafer, wafer to wafer, and lot to lot.

For example, as process geometries continue to decrease, critical dimensions (CD) of features of one or more layers of a semiconductor device fabricated on a wafer or other semiconductor substrate are becoming continually smaller, and variations in the CD across the wafer are increasing. CD may refer to the smallest dimension of a feature along a given direction, such as an opening/via width or diameter, or a tip-to-tip distance between adjacent trench ends. As CD variation increases, variation of performance characteristics of devices of the wafer also increases, which can lead to poor device performance and low yield.

Therefore, there is an ongoing need to improve the local CD uniformity, CD uniformity across a given wafer, and CD consistency from wafer to wafer.

### BRIEF DESCRIPTION OF THE DRAWINGS

The accompanying drawings illustrate exemplary approaches of the disclosure, including the practical application of the principles thereof, as follows:

FIG. 1A-1C demonstrate various device structures according to embodiments of the present disclosure;

FIG. 2A-2C demonstrate an example device structure including a plurality of openings, according to embodiments of the present disclosure;

FIG. 3A-3C demonstrate an example device structure including a plurality of openings during an ion process, according to embodiments of the present disclosure;

FIG. 4A-4C demonstrate an example device structure including a plurality of openings following the ion process, according to embodiments of the present disclosure;

FIG. 5A-5C demonstrate an example device structure including a plurality of openings, according to embodiments of the present disclosure;

FIG. 6A-6C demonstrate an example device structure including a plurality of openings during a first ion process, according to embodiments of the present disclosure;

FIG. 7A-7C demonstrate an example device structure including a plurality of openings following the first ion process, according to embodiments of the present disclosure;

FIG. 8A-8C demonstrate an example device structure including a plurality of openings during a second ion process, according to embodiments of the present disclosure; and

FIG. 9 illustrates a schematic diagram of a processing apparatus according to embodiments of the present disclosure.

### DETAILED DESCRIPTION

Embodiments herein describe methods, devices, and/or systems to provide adjustments to the CD of an opening (e.g., via, hole, trench, etc.) of a stack of layers using directional angled ion treatments. The methods, devices and systems may be embodied in many different forms and are not to be construed as being limited to the embodiments set forth herein. Instead, these embodiments are provided so the disclosure will be thorough and complete, and will fully convey the scope of the methods to those skilled in the art.

The embodiments of the present disclosure seek to address the challenges associated with producing openings having precise, nanometer-scale dimensions by using directional treatment (e.g., sputtering) and directional etch processes to modify openings formed in a stack of layers. These two processes, both individually and taken together, can act to modify the openings, while also reducing CD variability of the openings.

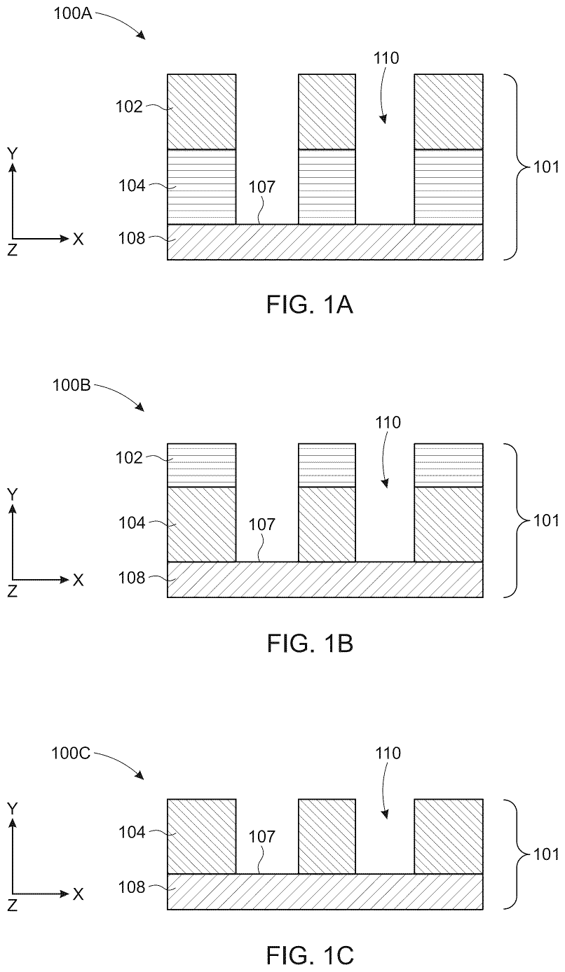

FIG. 1A a cross-sectional side view of a portion of a semiconductor device (hereinafter “device”) 100A, according to one or more embodiments of the disclosure. The device 100A may include a device layer structure or stack 101, including a first layer 102 formed over a second layer 104. The second layer 104 may be formed over an upper surface 107 of a substrate or base layer 108.

As further shown, the device 100A may include a plurality of openings (e.g., vias or trenches) 110 formed through the first and second layers 102, 104. The openings 110 extend to the upper surface 107 of the base layer 108, and may be formed using a variety of known processes (e.g., patterning and etching). The plurality of openings 110 may be formed as a grid or array of features across the device 100A. Although only two (2) openings 110 are shown for the sake of simplicity, it will be appreciated that many more openings 110 may be formed across the device 100A.

When the stack 101 is patterned, the openings 110 in the first and second layers 102, 104 are ideally formed with a desired shape having desired dimensions for transferring a desired etch pattern to the base layer 108 and/or other layers of the device 100. However, due to manufacturing constraints, it can be difficult or impossible to produce patterned masking material layers with openings having certain shapes with nanometer-scale dimensions with high reliability and precision, resulting in undesired CD variation.

In the embodiment shown, the first layer 102 may be a hardmask, such as a carbon-based film, e.g., advanced pattern film (APF), a spin-on hardmask (SOH), or amorphous carbon layer (ACL). In other embodiments, the first layer 102 may be a porous carbon, spin-on organic low-k dielectric materials, organic low-k dielectrics, and any combination thereof. In embodiments, the carbon-based film may formed using a chemical vapor deposition (CVD) or high density plasma CVD process.

The second layer 104 may be a silicon (Si) underlayer hardmask, e.g., amorphous silicon (aSi), silicon carbide (SiC), silicon boride (SiB), silicon dioxide (SiO2), silicon nitride (SiN), silicon oxynitride (SiON), etc. The second layer 104 may be formed (e.g., deposited) directly atop the upper surface 107 of the base layer 108.

Device 100B of FIG. 1B may include an alternative layer arrangement for the stack 101. For example, the first layer 102 may be a Si hardmask, while the second layer 104 may be a carbon-based film, e.g., APF, SOH, or ACL. Meanwhile, device 100C of FIG. 1C may include only second layer 104, which may be a carbon-based film, e.g., APF, SOH, or ACL. In other embodiments, the second layer 104 may be an extreme ultraviolet (EUV) lithography resist formed atop the base layer 108.

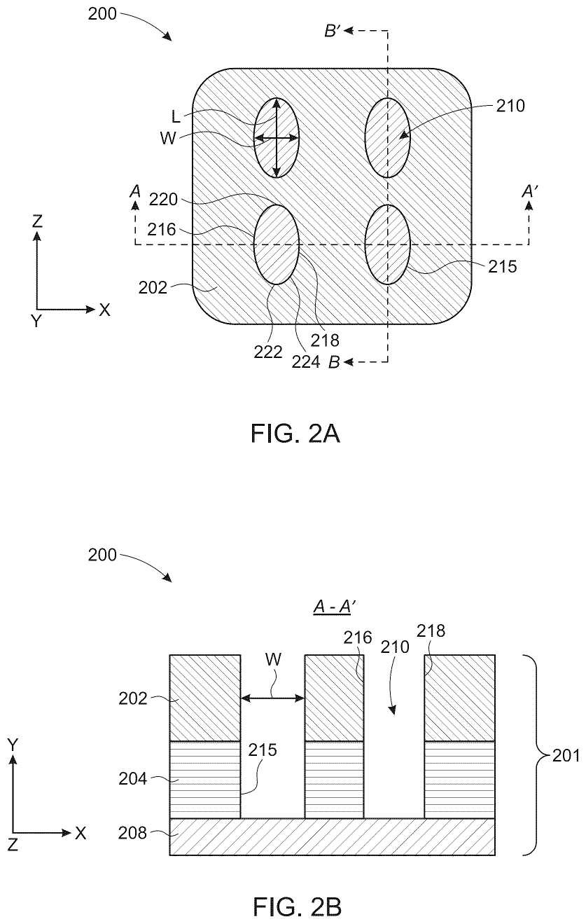

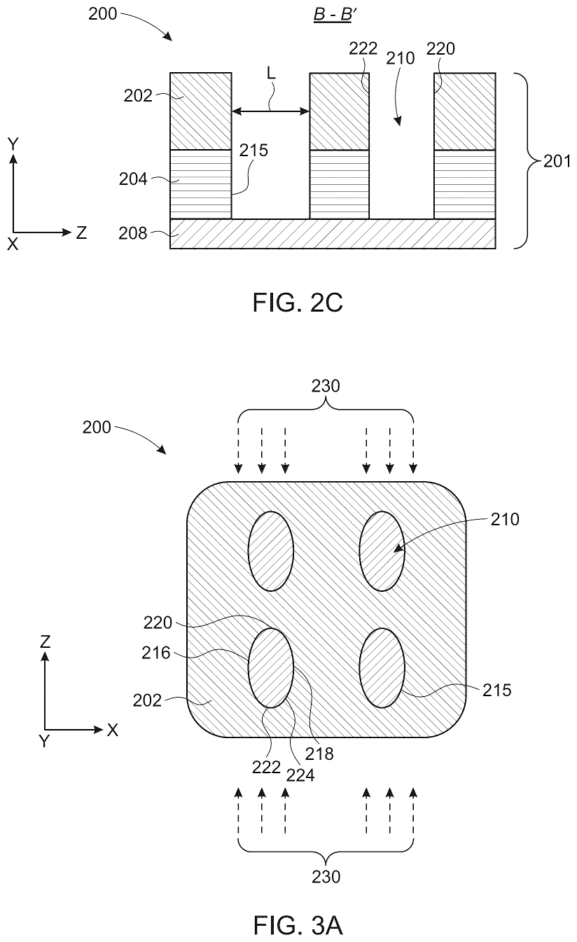

FIG. 2A is a simplified top view, and FIGS. 2B and 2C are cross-sectional views along cutlines A-A′ and B-B′ of FIG. 2A, respectively, of a portion of a semiconductor device (hereinafter “device”) 200, according to one or more embodiments of the disclosure. The device 200 may include a device stack 201 having a first layer 202 formed over a second layer 204. Although non-limiting, the device stack 201 may be substantially the same as stack 101 depicted in FIG. 1A. However, the processes described hereinafter may be similarly applied to devices 100B and 100C depicted in FIGS. 1B and 1C, respectively.

The device 200 may include a plurality of openings (e.g., vias) 210 formed through the first and second layers 202, 204. Each of the openings 210 may be defined by a sidewall 215. In the embodiment shown, each of the openings 210 may generally have an oval or oblong profile defining a width ‘W’ in the x-direction and a length ‘L’ in the z-direction. Each opening 210 may include a first side 216 opposite a second side 218, and a first end 220 opposite a second end 222. Each opening 210 may further include a set of connection areas 224 where the first and second ends 220, 222 meet the first and second sides 216, 218. These connection areas 224 may be curved/rounded. The plurality of openings 210 may be formed as a grid or array of features across the device 200. Although only four (4) openings 210 are shown for the sake of simplicity, it will be appreciated that many more openings 210 may be formed across the device 200.

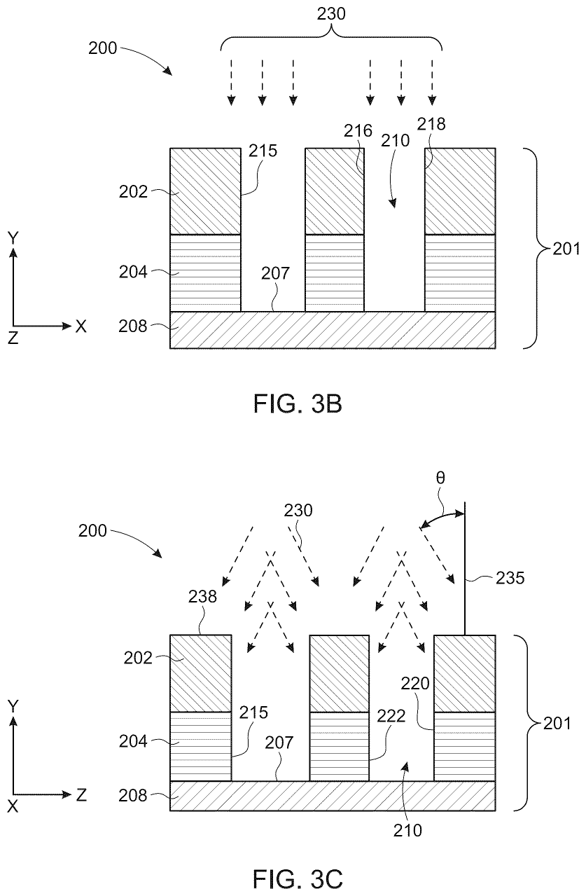

FIG. 3A-3C demonstrate the device 200 during a first ion process 230. In this embodiment, the first ion process 230 may be a directional ion sputtering process, which includes delivering/bombarding ions at a non-zero angle θ with respect to a line 235 (FIG. 3C) normal to an upper surface 238 of the first layer 202. In some embodiments, the non-zero angle θ is selected such that the ions impact substantially an entire height of sidewall(s) 215 of the openings 210 without significantly impacting an upper surface 207 of the substrate 208 within the openings 210. In some embodiments, the angle θ can be selected to have a value of between about 10° and about 70° with respect to the line 235 normal to the top surface of the first layer 202. Those having ordinary skill in the art will recognize, however, that other values for the angle θ can be selected to correspond to the dimensions of the openings 210.

More specifically, the first ion process 230 may include delivering ions to the sidewall(s) 215 of the openings 210 to cause the set of connection areas 224 to be “pushed” in the z-direction, i.e., to be removed faster than the first and second sides 216, 218 such that the set of connection areas 224 are squared off. The set of connection areas 224 may also be removed faster than at the first and second ends 220, 222. As such, the maximum width of the openings 210 is not significantly affected due to the first ion process 130. In various embodiments, the first ion process 230 may involve a specific gas type, e.g., dissociation ions, which may include at least one of the following ion chemistries: Ar+, N+, He+, H+, O+, CH+, CF+, CxHyF+, CO+, COS+, BCl3+, etc. The present disclosure is not limited in this regard, however.

Sputter yield is another important consideration of the first ion process 230. The sputter yield of a certain material can be optimized with a specific ion species, energy, and incidence angle. The dependencies of different materials vary in multi-dimensional space, and thus it is feasible to choose specific conditions as to select the desired ratio of sputter yields between multiple materials. For example, a high sputter yield at certain range of beam angles facilitates good carbon etch selectivity.

In some embodiments, the ions of the first ion process 230 can be sequentially emitted from one or more ion or plasma sources, wherein the substrate and/or the source(s) may be repositioned for a plurality of etch steps. For example, the substrate may be rotated about a central axis perpendicular to the upper surface 238 of the first layer 202 (e.g., in increments of 15 degrees, 45 degrees, 90 degrees, 180 degrees, etc.) after each of the plurality of treatment steps. Alternatively, the one or more ion or plasma sources can be rotated relative to device 200 about the central axis perpendicular to the upper surface 238 of the first layer 202. In addition, in some embodiments, the directional first ion process 230 can further act to decrease the height of the first layer 202.

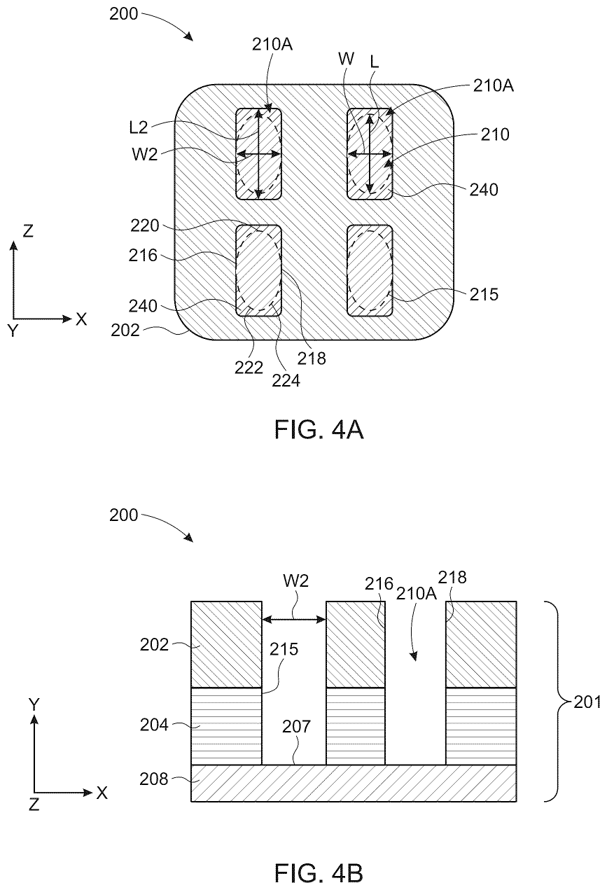

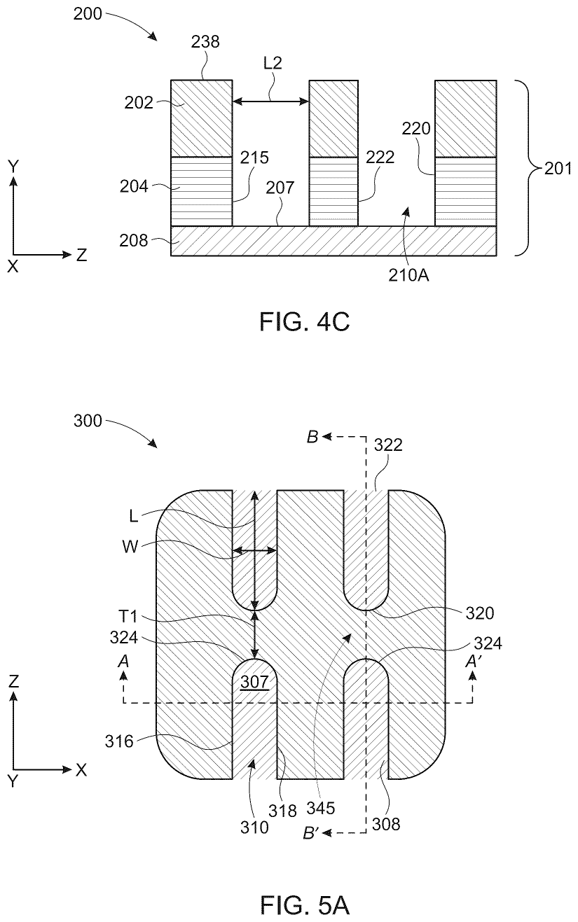

Following the first ion process 230, the set of connection areas 224 of the first end 220 and/or the second end 222 are enlarged to form openings 210A, including a set of corner regions 240, as depicted in FIG. 4A-4C. Broken lines in FIG. 4A depict the original openings 210 prior to the first ion process 230. As shown, the openings 210A now have a more rectangular profile as compared to the openings 210. However, following the first ion process 230, the openings 210A may have a width ‘W2’, which is the same, or substantially the same, as W1. Meanwhile, a length ‘L2’ of the openings 210A may be slightly larger than the length ‘L’ of the openings 210.

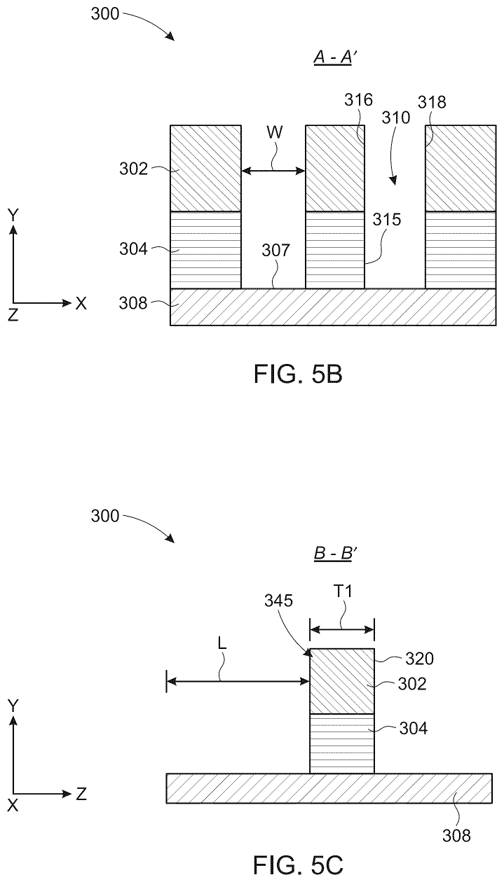

FIG. 5A is a simplified top view, FIG. 5B is a cross-sectional side view along cutline A-A′ of FIG. 5A, and FIG. 5C is a cross-sectional side view along cutline B-B′ of FIG. 5A of a portion of another semiconductor device (hereinafter “device”) 300, according to one or more embodiments of the disclosure. The device 300 may share many of the same features as device 200 and, as such, only certain aspects of the device 300 will hereinafter be described for the sake of brevity.

The device 300 may include a plurality of openings (e.g., elongated trenches or lines) 310 formed through a first layer 302 and a second layer 304, wherein the second layer 304 is formed directly atop an upper surface 307 of a substrate 308. Each of the openings 310 may be defined by a sidewall 315. As such, each of the openings 310 may have a width ‘W’ in the x-direction and a length ‘L’ in the z-direction, wherein the length is greater than the width (e.g., at least 10× greater). Each opening 310 may include a first side 316 opposite a second side 318, and a first end 320 opposite a second end 322. Each opening 310 may further include a set of connection areas 324 where the first end 320 meets the first and second sides 316, 318. In the embodiment shown, each connection area 324 is substantially curved/rounded.

As further shown, between two adjacent openings 310 is a tip-to-tip area 345. The tip-to-tip area 345 may be defined in part by a distance (T1) between a pair of facing first ends 320.

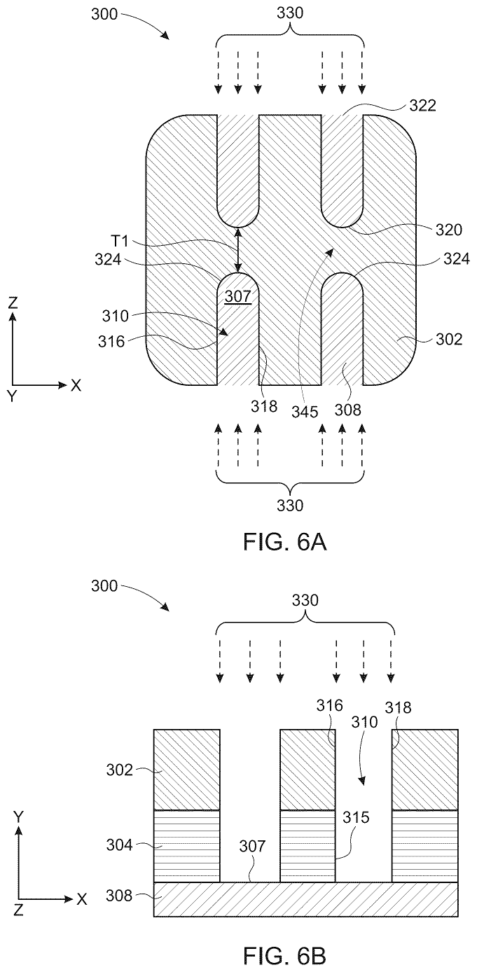

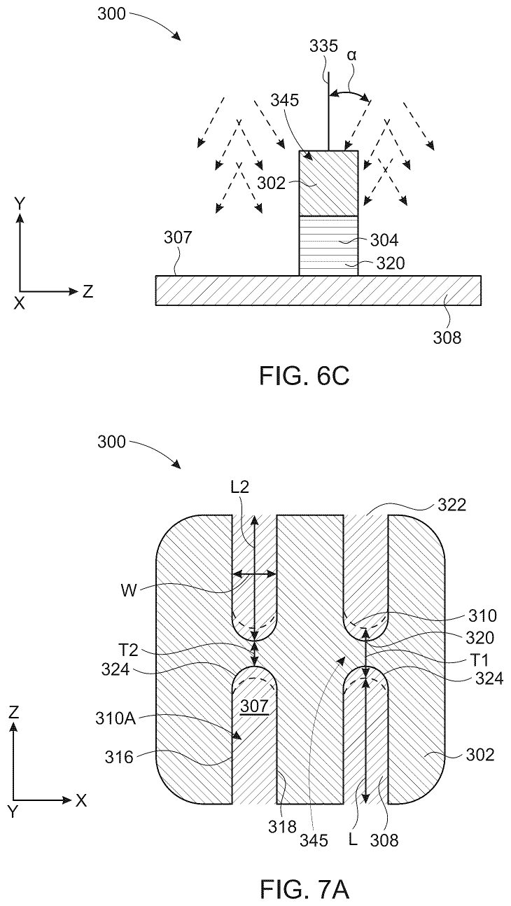

FIG. 6A-6C demonstrate the device 300 during a first ion process 330. In this embodiment, the first ion process 330 may be a directional ion etch (RIE) process, which includes delivering ions at a non-zero angle α with respect to a line 335 (FIG. 6C) normal to an upper surface of the first layer 302. In some embodiments, the non-zero angle α is selected such that the ions impact substantially an entire height of sidewall(s) 315 of the openings 310 without significantly impacting the upper surface 307 of the substrate 308 within the openings 310. In some embodiments, the angle α can be selected to have a value of between about 10° and about 70° with respect to the line 335 normal to the top surface of the first layer 302. Those having ordinary skill in the art will recognize, however, that other values for the angle α can be selected to correspond to the dimensions of the openings 310. In various embodiments, the ions of the first ion process 330 may include one or more chloro-fluorocarbon (CF) gasses or a mixture of chlorine gas (Cl₂) and hydrogen bromide gas (HBr) (Cl/HBR). Embodiments herein are not limited in this context, however.

In some embodiments, the ion beam can be sequentially emitted from one or more ion or plasma sources, wherein the substrate and/or the source(s) may be repositioned for a plurality of etch steps. For example, the substrate may be rotated about a central axis perpendicular to the surface of the upper surface 307 of the substrate 308 (e.g., in increments of 15 degrees, 45 degrees, 90 degrees, 180 degrees, etc.) after each of the plurality of etch steps. Alternatively, the one or more ion or plasma sources can be rotated relative to the upper surface 307 of the substrate 308 about the central axis after each of the plurality of etch steps. In addition, in some embodiments, the directional etch process can further act to decrease the height of the first layer 302.

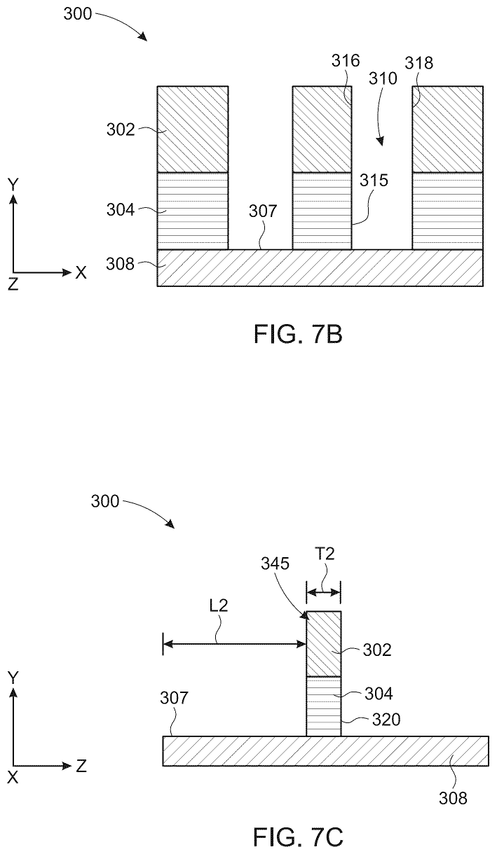

Following the etch process to the first and second layers 302, 304, the openings 310 may be enlarged in the z-direction without being significantly enlarged in the x-direction, e.g., as shown in FIG. 7A-7C. Broken lines in FIG. 7A depict the original openings 310 prior to the first ion process 330. As shown, the openings 310A now have a length ‘L2’, which is greater than the length (L) of the original openings 310. Furthermore, as a result of the first ion process 330, the original tip-to-tip distance (T1) of the tip-to-tip area 345 has been reduced, as shown by distance ‘T2’.

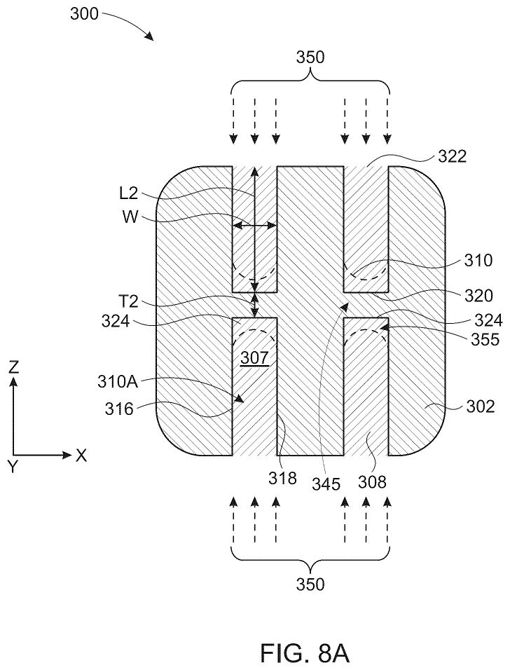

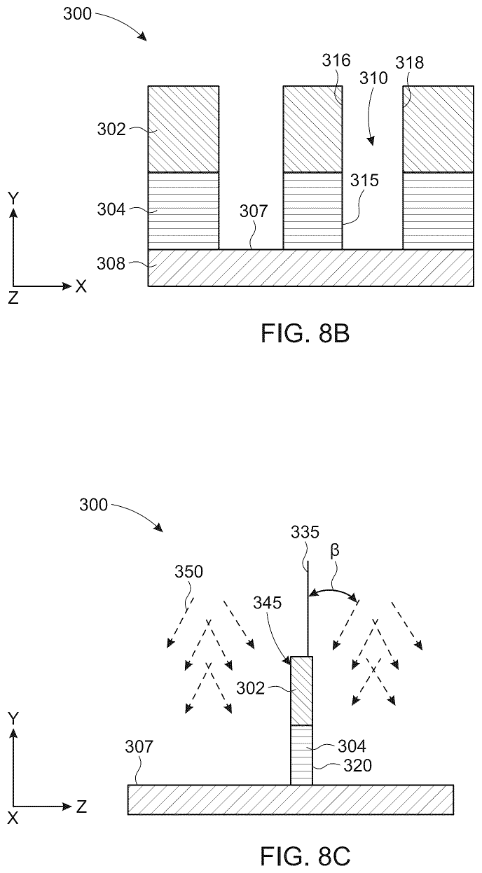

In some embodiments, as shown in FIG. 8A-8C, a second ion process 350 may then be performed on the device 300. In this embodiment, the second ion process 350 may be a directional ion sputtering process, which includes delivering/bombarding ions at a non-zero angle β with respect to the line 335 (FIG. 8C) normal to the upper surface of the first layer 302. In some embodiments, the non-zero angle β is selected such that the ions impact substantially an entire height of sidewall(s) 315 of the openings 310A without significantly impacting an upper surface 307 of the substrate 308 within the openings 310A. In some embodiments, the angle β can be selected to have a value of between about 10° and about 70° with respect to the line 335. Those having ordinary skill in the art will recognize, however, that other values for the angle β can be selected to correspond to the dimensions of the openings 310A.

More specifically, the second ion process 350 may include delivering ions to the sidewall(s) 315 of the openings 310A to cause the set of connection areas 324 to be “pushed” in the z-direction, i.e., to be removed faster than the first and second sides 316, 318 such that the set of connection areas 324 are squared off at the first end 320. Said another way, the second ion process 350 results in a set of corner regions 355 being formed at each of the first ends 320. In various embodiments, the first ion process 230 may involve a specific gas type, e.g., dissociation ions, which may include at least one of the following ion chemistries: Ar+, N+, He+, H+, O+, CH+, CF+, CxHyF+, CO+, COS+, BCl3+, etc. The present disclosure is not limited in this regard, however. In some embodiments, the first ion process 330 (FIG. 6A-6C) may then be repeated, as desired, to form the openings 310 with the desired squared profile and tip-to-tip distance. In still other embodiments, the second ion process 350 may be performed before the first ion process 330. That is, the openings 310 may first be sputtered to form squared ends, followed by an angled etch process to increase a length of the openings.

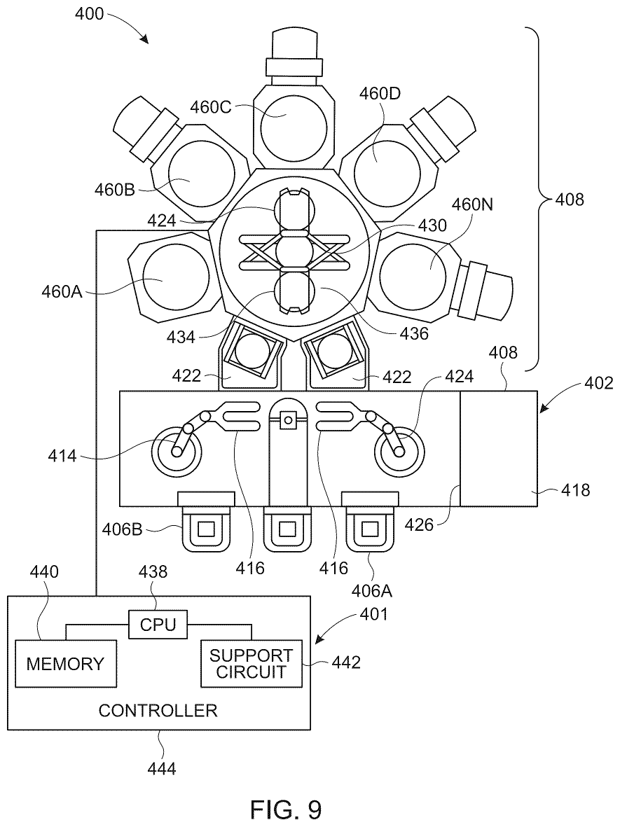

FIG. 9 is a schematic top plan view of an exemplary cluster processing system 400 that includes one or more of the processing chambers operable to form the devices 100A-100C, 200, and 300 described herein. In one embodiment, the cluster processing system 400 may be an integrated processing system commercially available from Applied Materials, Inc., located in Santa Clara, CA. It is contemplated that other processing systems (including those from other manufacturers) may be adapted to benefit from the disclosure.

The cluster processing system 400 may include a vacuum-tight processing platform 404, a factory interface 402, and a system controller 444. The platform 404 includes a plurality of processing chambers 460A-460N and at least one load-lock chamber 422 that is coupled to a vacuum substrate transfer chamber 436. The factory interface 402 is coupled to the transfer chamber 436 by the load lock chambers 422.

In one embodiment, the factory interface 402 comprises at least one docking station 408 and at least one factory interface robot 414 to facilitate transfer of substrates. The docking station 408 is configured to accept one or more front opening unified pod (FOUP). The factory interface robot 414 having a blade 416 disposed on one end of the robot 414 is configured to transfer the substrate from the factory interface 402 to the processing platform 404 for processing through the load lock chambers 422. Optionally, one or more metrology stations 418 may be connected to a terminal 426 of the factory interface 402 to facilitate measurement of the substrate from the FOUPS 406A-B.

Each of the load lock chambers 422 have a first port coupled to the factory interface 402 and a second port coupled to the transfer chamber 436. The load lock chambers 422 are coupled to a pressure control system (not shown) which pumps down and vents the load lock chambers 422 to facilitate passing the substrate between the vacuum environment of the transfer chamber 436 and the substantially ambient (e.g., atmospheric) environment of the factory interface 402.

In one embodiment of the cluster processing system 400, the cluster processing system 400 may include one or more processing chambers 460A-460N, which may include a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, implant chamber, lithographic exposure chamber, or other similar type of semiconductor processing chambers. More specifically, etch chamber 460A may include an etch tool operable to perform an angled etch using a reactive plasma beam delivered at a non-zero angle, as described herein with respect to device 300. Meanwhile, deposition chamber 460B may include an ion treatment tool operable to perform an angled ion sputtering process delivered at a non-zero angle to enhance/enlarge portions of openings, such as corner areas of vias or trenches, as described herein with respect to devices 100, 200, and 300. In other embodiments, the etch and ion sputtering processes can be performed in the same chamber, such as an angled plasma beam chamber, e.g., by changing the chemistry being used in the chamber. The etch and ion sputtering processes may occur sequentially, but they may also occur simultaneously, by running both the etch and the bombardment chemistries at the same time.

The transfer chamber 436 has a vacuum robot 430 disposed therein. The vacuum robot 430 has a blade 434 capable of transferring substrates 424 among the load lock chambers 422, the metrology system 410 and the processing chambers 460A-460N.

The system controller 444 is coupled to the cluster processing system 400. The system controller 444, which may include the computing device 401 or be included within the computing device 401, controls the operation of the cluster processing system 400 using a direct control of the processing chambers 460A-460N of the cluster processing system 400. Alternatively, the system controller 444 may control the computers (or controllers) associated with the processing chambers 460A-460N and the cluster processing system 400. In operation, the system controller 444 also enables data collection and feedback from the respective chambers to optimize performance of the cluster processing system 400.

The system controller 444, much like the computing device 401 described above, generally includes a central processing unit (CPU) 438, a memory 440, and support circuits 442. The CPU 438 may be one of any form of a general-purpose computer processor that can be used in an industrial setting. The support circuits 442 are conventionally coupled to the CPU 438 and may comprise cache, clock circuits, input/output subsystems, power supplies, and the like. The software routines transform the CPU 438 into a specific purpose computer (controller) 444. The software routines may also be stored and/or executed by a second controller (not shown) that is located remotely from the cluster processing system 400.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
forming a plurality of openings in a material layer stack formed over a substrate, wherein each opening of the plurality of openings comprises a first side opposite a second side, a first end opposite a second end, and a set of connection areas between the first end and the first and second sides; and
performing a first ion process on the material layer stack to modify one or more dimensions of the set of connection areas, wherein the first ion process comprises directing ions to the material layer stack at a first non-zero angle relative to a normal direction extending from a top surface of the material layer stack.

2. The method of claim 1, further comprising performing a second ion process on the material layer stack to modify one or more dimensions of the plurality of openings, wherein the second ion process comprises performing an angled ion etch by delivering an ion beam at a second non-zero angle relative to the normal direction extending from the top surface of the material layer stack.

3. The method of claim 2, wherein modifying one or more dimensions of the plurality of openings as a result of the second ion process comprises removing a portion of the material layer stack at the first end of the plurality of openings to enlarge the plurality of openings.

4. The method of claim 1, wherein modifying one or more dimensions of the set of connection areas as a result of the first ion process comprises forming a set of squared ends.

5. The method of claim 1, wherein the material layer stack comprises a first hardmask formed over a second hardmask, and wherein the second hardmask is formed over an upper surface of the substrate.

6. The method of claim 1, wherein the first ion process is an ion sputtering process.

7. The method of claim 1, wherein the ions of the first ion process comprise at least one of the following: argon, xenon, nitrogen, helium, hydrogen, and oxygen.

8. The method of claim 1, wherein the first ion process comprises directing ions into a sidewall at the first end of the plurality of openings.

9. A method of modifying an opening in a material layer stack provided on a substrate, the method comprising:
forming a plurality of openings in the material layer stack, wherein each opening of the plurality of openings comprises a first side opposite a second side, a first end opposite a second end, and a set of connection areas between the first end and the first and second sides; and
performing a first ion process on the material layer stack to modify one or more dimensions of the set of connection areas, wherein the first ion process comprises directing ions to a sidewall of the plurality of openings at a first non-zero angle relative to a normal direction extending from a top surface of the material layer stack.

10. The method of claim 9, further comprising performing a second ion process on the material layer stack to modify one or more dimensions of the plurality of openings, wherein the second ion process comprises performing an angled ion etch by delivering an ion beam at a second non-zero angle relative to the normal direction extending from the top surface of the material layer stack.

11. The method of claim 10, wherein modifying one or more dimensions of the plurality of openings as a result of the second ion process comprises removing a portion of the material layer stack at the first end of the plurality of openings to enlarge the plurality of openings.

12. The method of claim 9, wherein modifying one or more dimensions of the set of connection areas as a result of the first ion process comprises forming a set of squared ends.

13. The method of claim 9, wherein the material layer stack comprises a first hardmask formed over a second hardmask, and wherein the second hardmask is formed over an upper surface of the substrate.

14. The method of claim 9, wherein the first ion process is an ion sputtering process.

15. The method of claim 9, wherein the ions of the first ion process comprise at least one of the following: argon, xenon, nitrogen, helium, hydrogen, and oxygen.

16. An ion processing tool, comprising:
a plasma chamber for generating plasma, wherein ions are extracted from the plasma and directed to a semiconductor device; and
a main controller operatively coupled to plasma chamber, wherein the main controller is adapted to perform a first ion treatment to modify one or more dimensions of a set of connection areas of a plurality of openings formed through a material layer stack, wherein the material layer stack is formed atop a substrate, wherein the first ion treatment comprises directing ions to a sidewall of the plurality of openings at a first non-zero angle relative to a normal direction extending from a top surface of the material layer stack.

17. The ion processing tool of claim 16, wherein the main controller is further adapted to perform a second ion treatment on the material layer stack to modify one or more dimensions of the plurality of openings, wherein the second ion treatment comprises performing an angled ion etch by delivering an ion beam at a second non-zero angle relative to the normal direction extending from the top surface of the material layer stack.

18. The ion processing tool of claim 17, wherein modifying one or more dimensions of the set of connection areas as a result of the first ion treatment comprises forming a set of squared ends, and wherein modifying one or more dimensions of the plurality of openings as a result of the second ion treatment comprises removing a portion of the material layer stack at the first end of the plurality of openings to enlarge the plurality of openings.

19. The ion processing tool of claim 16, wherein the material layer stack comprises a first hardmask formed over a second hardmask, and wherein the second hardmask is formed over an upper surface of the substrate.

20. The ion processing tool of claim 16, wherein the first ion treatment is an ion sputtering process comprising at least one of the following: argon, xenon, nitrogen, helium, hydrogen, and oxygen.
